(19) United States
(12) Patent Application Publication
(10) Pub. No.: US 2008/0218186 A1
(43) Pub. Date: Sep. 11, 2008

(54) Image sensing integrated circuit test apparatus and method

(76) Inventors: Jeff Kooiman, San Jose, CA (US); Alden Carracillo, Temse (BE)

Correspondence Address: Haverstock & Owens- Cypress, 162 North Wolfe Road, Sunnyvale, CA, 94086, US

(21) Appl. No.: 11/715,535

(22) Filed: Mar. 7, 2007

(51) Int. Cl. G01R 31/02

(52) U.S. Cl. 324/754

(57) ABSTRACT

An image sensing integrated circuit test device can include a plurality of conductive leads for making electrical contact with at least one integrated circuit device under test. A light directing structure can direct light onto the at least one integrated circuit device under test. The light directing structure includes a top member disposed in a lateral direction and having at least one aperture formed therein. For each aperture, a blocking member can be attached to the top member and disposed in a longitudinal direction around the aperture. The blocking member can prevent light arriving through the aperture from propagating in the lateral direction.

### TECHNICAL FIELD

The present invention relates generally to integrated circuit testing, and more particularly to the testing of image sensing integrated circuit devices.

### BACKGROUND OF THE INVENTION

Image sensor integrated circuits typically include a portion for receiving and detecting light, such as an imaging array. Conventionally, image sensor integrated circuits are manufactured in wafer form and then subsequently separated (e.g., sawed) into individual dice. Each die can then be packaged.

As part of a testing program, most conventional processes can test integrated circuits while in wafer form. A typical test assembly utilized in a wafer test is a probe card. A probe card can include a circuit board, or the like, for both applying and receiving test signals of a tested integrated circuit. Unlike other types of integrated circuits, in order to adequately test an image sensor, it is desirable to apply light to the integrated circuit device being tested.

To better understand various features of the disclosed embodiments, a conventional image sensor integrated circuit test approach will now be described.

Referring now to FIG. 7A, a conventional probe card for testing image sensor integrated circuits is shown in a top plan view and designated by the general reference character 700. Probe card 700 can include a circuit board portion 702 and a pupil module 704. A circuit board portion 702 can include electrical interconnections for inputting test signals from a tester to one or more integrated circuits being tested (devices under test, or “DUTs”), as well as outputting test signals from DUTs to the tester. A pupil module 704 can fit into an opening of probe card 702, and can apply light received on a top surface of the probe card 702 onto one or more DUTs below by focusing such light with lenses.

Referring now to FIG. 7B, a conventional pupil module 704 is shown in an exploded side cross sectional view. Pupil module 704 can include a visor 706, a pupil lens module 708, a base unit 710, and a reinforcement board 712. A visor 706 can allow light to be provided to pupil lens module 708. Pupil lens module 708 can include a number of pupil lenses positioned adjacent to one another. FIG. 7B shows a pupil lens module 708 having eight pupil lenses. Each pupil lens can focus received light onto a different DUT. A base unit 710 can serve to hold lenses of pupil lens module 708 in a fixed position. A reinforcement board 712 can hold base unit, and provide a location for attaching pupil module 704 to probe card 702.

Referring now to FIG. 7C, the optics of a pupil lens 708-0, like one of those included in pupil lens module 708, are shown in a diagram. Light 720 can be received at an upper end of a pupil lens 708-0 and then focused by a lens area 722. Focused light can be output at a pupil exit position 724 and onto a DUT 726. FIG. 7D shows an outside view of a pupil lens 708-0.

A conventional focusing test system, like that described above, can be preferred for testing image sensors having shifted color filters and/or microlenses. The difference between illumination resulting from a focusing lens versus that of diffused light is shown in FIGS. 8A and 8B. Both FIGS. 8A and 8B show an integrated circuit substrate 802 that can include photo diodes (one shown as 803) for converting incident light into charge. Formed over substrate 802 can be microlenses and color filters 804. Each microlens and filter can be shifted in a direction parallel to a substrate surface with respect to a photo diode below.

FIG. 8A shows illumination 806 resulting from diffused light. An area 808 shows photo diodes that are illuminated in the diffused light case. FIG. 8B shows illumination 810 resulting from light applied via a lens. An area 814 shows a photo diode illuminated by such a lens.

A drawback to a conventional approach like that described above can be the complexity of the assembly required to test image sensors. A conventional pupil lens module has a multiple layer stack of components, including a pupil lens that must be provided for each device tested. As a result, a pupil lens module can be expensive to implement.

Further, there is very little tolerance in component placements for the module. If any component is not placed correctly, one or more DUTs may not receive the proper illumination for a test.

### BRIEF DESCRIPTION OF THE DRAWINGS

FIGS. 1A and 1B show top plan and side cross sectional views of a test system according to a first embodiment of the present invention.

FIGS. 2A to 2D show top plan, bottom plan, and side cross sectional views of a test system according to a second embodiment of the present invention.

FIG. 3 is a diagram illustrating one example of a pin hole optic arrangement for providing light to device under test according to one embodiment.

FIGS. 4A and 4B show top plan views of a testing arrangement for a test system like that shown in FIGS. 2A to 2D.

FIGS. 5A to 5F show top plan, bottom plan, and side cross sectional views of a test system and arrangement according to another embodiment.

FIGS. 6A to 6D show top plan, bottom plan, and side cross sectional views of a test system and arrangement according to another embodiment.

FIG. 7A to 7D are various views showing a conventional probe card and associated components for testing an image sensor integrated circuit.

FIGS. 8A and 8B are side views showing a portion of an image sensor subjected to diffused light versus light from a lens.

### DETAILED DESCRIPTION

Various embodiments of the present invention will now be described in detail with reference to a number of drawings. The embodiments show test devices and methods for testing image sensor integrated circuits (ICs) that can rely on the application of light to a device under test (DUT) by way of a pinhole opening, as opposed to a focusing lens. The embodiments can also allow for fine position adjustment of light transmitting components and can test image sensor ICs in both wafer and packaged form.

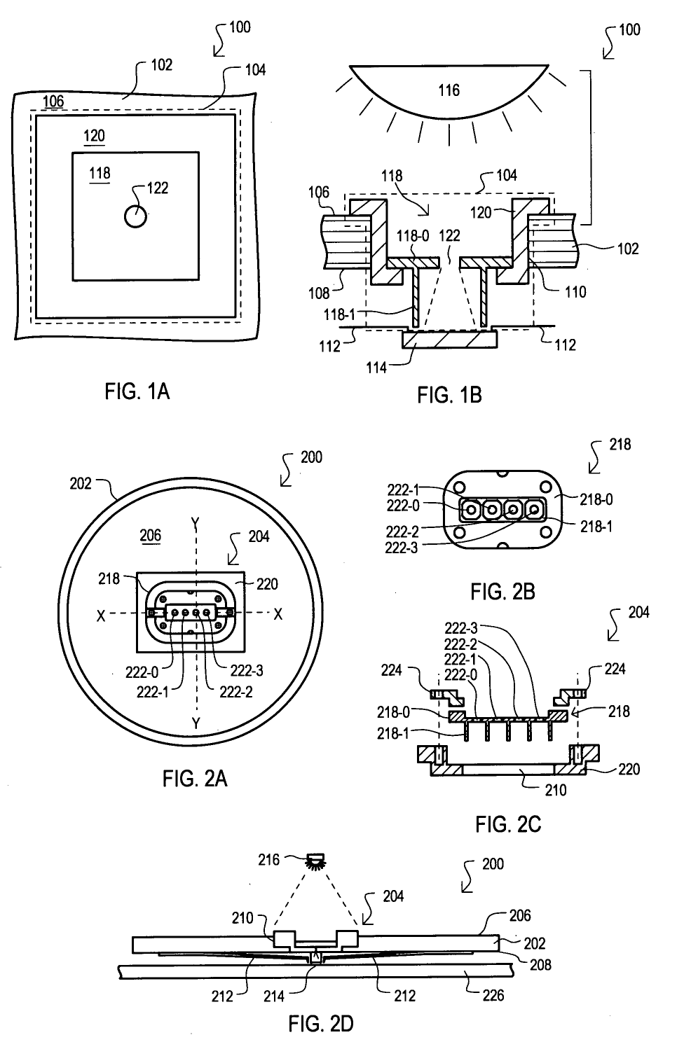

A test device according to a first embodiment is shown in a number of views in FIGS. 1A and 1B, and designated by the general reference character 100. A test device 100 can be part of a test system for testing image sensor ICs. FIG. 1A is a top plan view of a test device 100. FIG. 1B is a side cross sectional view of test device 100.

Referring now to FIGS. 1A and 1B, a test device 100 can include a card portion 102 and a light providing assembly 104. A card portion 102 can include a top surface 106, a bottom surface 108 (not shown in FIG. 1A), and an opening 110 (also not shown in FIG. 1A). In addition, a card portion 102 can include electrical connections 112 to a DUT 114. Electrical connections 112 can provide signals to and/or receive signals from a DUT 114. Electrical connections 112 can take a variety of forms according to the particular form of the DUT 114 (i.e., wafer form, or packaged form). More detailed examples of electrical connections will be shown in other embodiments below.

A light providing assembly 104 can be positioned within opening 110 of card portion 102. A light providing assembly 104 can provide a path for light generated from a light source 116 above a top surface 106 to a DUT 114 positioned below a bottom surface 108 of card portion 102. In the example shown, a light providing assembly 104 can include light direction structure 118 and a base 120.

Referring still to FIGS. 1A and 1B, in the embodiment shown, light providing assembly 118 includes an aperture 122 for directing light onto a DUT 114. An aperture 122 can be an essentially non-focusing aperture. That is, optics are not utilized to focus light onto a DUT 114. Preferably, an aperture 122 can provide light via “pin hole” optics. That is, an aperture 122 can be an opening that presents no interfering structure between a light source 116 and a DUT 114, or that includes a non-focusing transparent element. Even more preferably, apertures 108 can be an opening that is circular in shape.

Referring to FIG. 1B, a light providing assembly 118 can include a horizontal portion 118-0 and, optionally, a vertical blocking portion 118-1. A horizontal portion 118-0 can be essentially parallel to a surface of a DUT 114 that receives light. A light blocking portion 118-1 can extend from a horizontal portion 118-0 in a direction toward a DUT 114 and can block light from being transmitted in a direction perpendicular to aperture 122.

In this way, a test device can include a light directing structure that provides light to a DUT without focusing optics.

While the first embodiment described above shows one aperture, it is understood that other embodiments can include multiple apertures for testing more than one DUT at a time. In addition, for greater flexibility in a test system, other embodiments can provide some fine position adjustment in any of three dimensions. One very particular example of such an embodiment is shown in FIGS. 2A to 2D.

Referring now to FIG. 2A, a test system is shown in a top plan view and designated by the general reference character 200. A test system 200 can include some of the same general components as the first embodiment. Thus, like components are referred to by the same reference character but with the first digit being a “2” instead of a “1”.

In the particular examples of FIGS. 2A to 2D, a card portion 202 can be a probe card for testing multiple ICs in wafer form. In such an arrangement, DUTs can be integrated circuits formed in the same substrate that have not yet been separated or packaged. A card portion 202 can include conventional circuitry for providing signals from and to a device under test (DUT). In one a particular example, a card portion 202 can include a printed circuit board having interconnection patterns between layers and/or on either or both of the surfaces, as well as electronic components for receiving, transmitting, or conditioning test signals.

As in the case of FIGS. 1A and 1B, a light providing assembly 204 can provide a path for light through card portion 202. However, FIG. 2A shows an arrangement in which light can be provided for four different DUTs. In the particular embodiment shown, a light providing assembly 204 includes a light directing structure 218 attached to a base 220. Light directing structure 218 can include four, non-focusing apertures (222-0 to 222-3) aligned with one another along a common axis. In addition, a light directing structure 218 can be adjustable in position with respect to a base 220. More particularly, a light directing structure 218 can be raised or lowered in position with respect to a base 220. Such a feature can be accomplished by screws, bolts, spacers, or clamps, as but a few examples. In addition or alternatively, a light directing structure 218 can be moved in a lateral (i.e., X-Y) direction with respect to a base 220. Such movement can also be accomplished by screws, bolts, spacers, clamps, or even an X-Y translation assembly, such as a rack and pinion assembly, to name but a few possible approaches.

Referring now to FIG. 2B, a light directing structure 218 is shown in a bottom plan view. Each aperture (222-0 to 222-3) can be surrounded by light blocking portion 218-1. Thus, light received from one aperture for one DUT can be prevented from interfering with an adjacent DUT.

Referring now to FIG. 2C, a light providing assembly 204 is shown in a side cross sectional view taken along line X-X of FIG. 2A. A base 220 can receive light directing structure 218. In the particular example shown, a light directing structure 218 can be physically held in place with respect to base 220 by clamping members 224. As but one example, clamping members 224 can be attached to a base by bolts and threaded openings. Preferably, light directing structure 218 can be adjusted in a lateral direction (X and/or Y) prior to being fixed in place.

Of course, alternate embodiments could include different ways of adjusting position and/or fixing a light directing structure to a base.

Referring now to FIG. 2D, a test system 200 is shown in a side cross sectional view taken along line Y-Y of FIG. 2A. As shown by FIG. 2D a light source 216 can be situated above a top surface 206 of card portion 202, and light can pass through light providing assembly 204 to a DUT 214. In the example shown, a DUT 214 can be an IC formed in a wafer 226.

FIG. 2D also shows one particular example of electrical connections 212. In the example shown, electrical connections 212 can be probe card “needle” type connections that extend more in a lateral direction (i.e., parallel to a bottom surface 208) than in a longitudinal direction (i.e., perpendicular to a bottom surface 208). Probe card needles can contact bond pads on an IC, and provide power and test signals to the DUT(s).

In this way, a test device can include a light directing structure that provides light without focusing optics to multiple DUTs, and can include fine position adjustments in one, two or three dimensions.

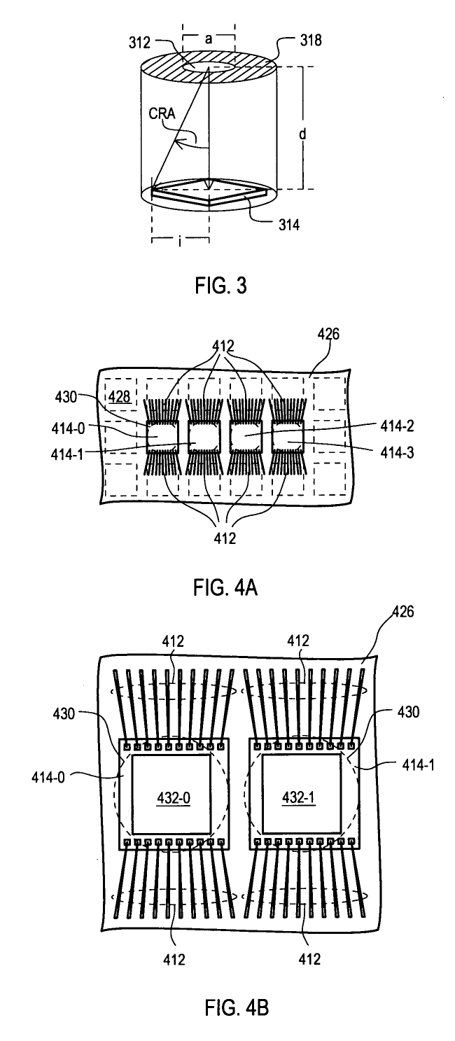

Referring now to FIG. 3, a diagram illustrates one very particular example of the application of light onto a DUT utilizing non-focusing, pin hole optics, like those of the embodiments. Diffuse light can enter a pin hole aperture 312 having a diameter “a”. Alternatively, an aperture 312 can include a light diffusing, transparent structure, such as “milk” glass. However, aperture 312 does not include any focusing effects, such as that provided by a converging lens, or the like. Based on angle “CRA”, a DUT 314 can be positioned a distance “d” below aperture 312 to provide a desired exposure length (½ diagonal) “i”. In one very particular example, an aperture diameter “a” can be 1.79 millimeters (mm) and angle “CRA” can be about 62°. This can result in a length “i” of 2.3 mm at a distance “d” of 5 mm.

Of course, FIG. 3 represents but one example, and the dimensions noted should not be construed as limiting to the invention.

As noted above, a test system like that shown in FIGS. 2A to 2D can test multiple DUTs at the same time. One particular arrangement for doing so is shown in FIGS. 4A and 4B.

FIG. 4A is a top plan view of a testing arrangement that can correspond to the test system shown in FIGS. 2A to 2D. FIG. 4A shows a portion of a tested wafer 426. A wafer 426 can include multiple ICs, one of which is shown as 428. Of the numerous ICs, four ICs can be DUTs 414-0 to 414-3 of a same row. A set of electrical connections 412 can make contact with each DUT (414-0 to 414-3). The electrical connections 412 of FIGS. 4A and 4B can be needle type probes of a probe card. FIG. 4A also shows image areas for each DUT, one of which is shown as 430. An image area 430 can be a resulting area lit according to light passing through a corresponding aperture.

FIG. 4B is a magnified view of FIG. 4A, showing DUTs 414-0 and 414-1 in more detail. Each DUT (414-0 and 414-1) can include test point contacts (in this case bond pads, or the like), situated only on two opposing sides of each die. This can allow testing of a row of ICs, as test connections can be applied only from opposite directions. In the particular example shown in FIG. 4B, each DUT (414-0 and 414-1) has an image sensor array 432-0 and 432-1. The image areas 430 of the DUTs (414-0 and 414-1) can completely surround the corresponding image sensor array (432-0 and 432-1).

In this way, multiple integrated circuit devices in wafer form can be tested at one time. Of course, fewer or more than four DUTs of a same row could be tested at one time according to available area of a test system (e.g., probe card). Along these same lines, provided sufficient room was available for needle type probes, more than one row could be tested at the same time.

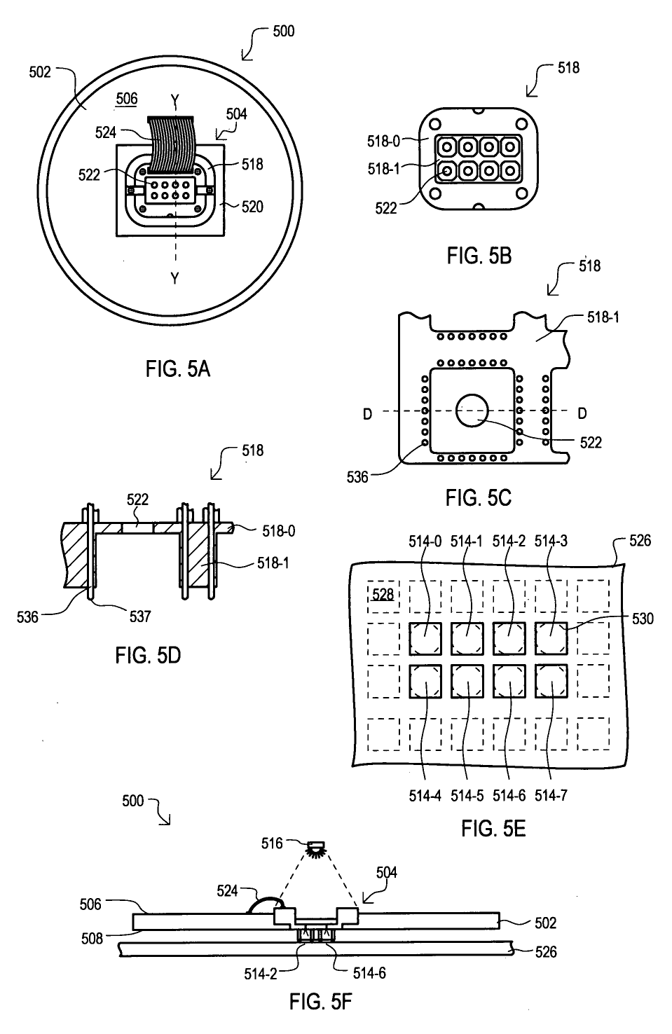

While the arrangement of FIGS. 4A and 4B show the testing of a single row of ICs in a wafer, alternate embodiments can include the testing of multiple rows and utilize different test probe technologies. Further, such alternate embodiments can test dice having probe locations (e.g., bond pads) on three or more sides. One example of such an approach is shown in FIGS. 5A to 5F.

Referring now to FIG. 5A, a test system is shown in a top plan view and designated by the general reference character 500. A test system 500 can include some of the same general components as the embodiment of FIG. 2A, thus, like components are referred to by the same reference character but with the first digit being a “5” instead of a “2”.

Unlike the arrangement of FIG. 2A, the test system 500 of FIG. 5A has a light providing assembly 504 in which light can be provided to multiple rows of DUTs. In the particular embodiment shown, a light providing assembly 504 can include eight, non-focusing apertures (one of which is shown as 522) aligned with one another along two parallel axes. As in the case of FIG. 5A, a light directing structure 518 can be adjustable in position with respect to a base 520.

FIG. 5A also shows a test device 500 that includes “vertical” probes. Vertical probes can extend in a vertical direction downward from test device 500 and onto one or more DUTs. In the particular example illustrated, vertical probes can be incorporated into a light providing assembly 504. Thus, test device 500 can include an electrical connection 524 between a light providing assembly 504 and a card portion 502.

Referring now to FIG. 5B, a light directing structure 518, like that shown in FIG. 5A, is shown in a bottom plan view. Each aperture (one shown as 522) can be surrounded by light blocking portion 518-1. Thus, light received from one aperture for one DUT can be prevented from interfering with an adjacent DUT.

Referring now to FIG. 5C, a portion of a light directing structure 518 is shown in a magnified bottom plan view. Unlike arrangements incorporating needle type probes, light directing structure 518 can include vertical probes (one shown as 536) for providing electrical connection to a DUT. While the arrangement of FIG. 5C shows vertical probes that can contact bond pads on all four sides of a DUT, alternate embodiments can include probes on two opposing sides for compatibility with ICs like those shown in FIG. 4B.

Referring now to FIG. 5D, a magnified portion of a light directing structure 518 is shown in a side cross sectional view taken along line D-D of FIG. 5C. In the very particular arrangement shown, vertical probes (one shown as 536) can be situated within light blocking portion 518-1, and include contact points (one shown as 537) for contacting a test point (e.g., bond pad) of a DUT.

Referring now to FIG. 5E, a top plan view shows a testing arrangement that can correspond to the test system shown in FIGS. 5A to 5D. FIG. 5E shows a portion of a tested wafer 526 having multiple ICs formed therein (one shown as 528). Eight of the ICs can be DUTs 514-0 to 514-7. Like FIG. 4A, FIG. 5E also shows image areas for each DUT (one of which is shown as 530).

Referring now to FIG. 5F, a test system 500 is shown in a side cross sectional view taken along line Y-Y of FIG. 5A. As noted above, FIG. 5F shows one particular example in which electrical connections for DUTs can be vertical type probes that extend in an essentially vertical direction from a bottom surface 508 of card portion 502 only DUT(s) (514-2, 514-6).

In this way, multiple rows of IC devices in wafer form can, be tested at one time. In addition, a test system 500 can include vertical type probes for making contact with such IC devices at bond pads on more than two sides of an IC device. It is noted that while FIGS. 5C and 5D show vertical type test probes, alternate embodiments can include different probe types formed on a bottom surface of a light blocking portion (e.g., 518-1). As but one example, test probes can be micro-electromechanical (MEM) type test probes.

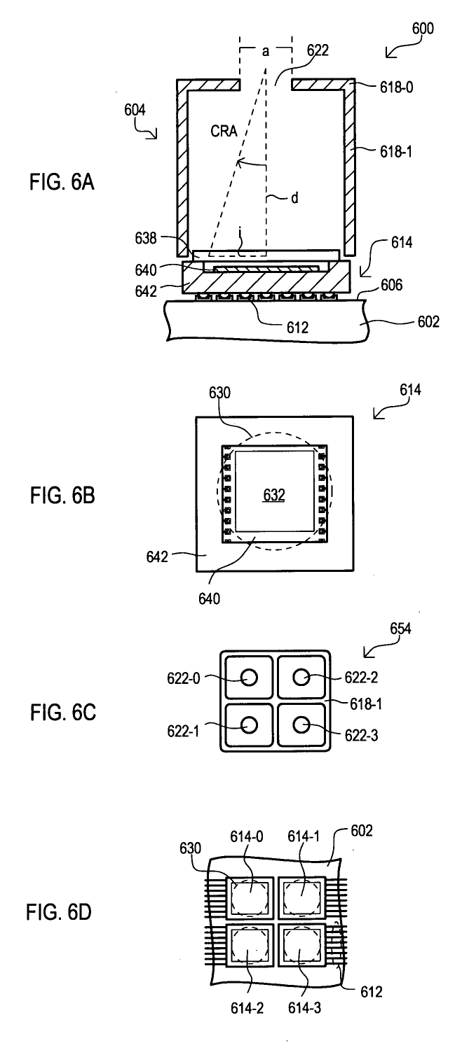

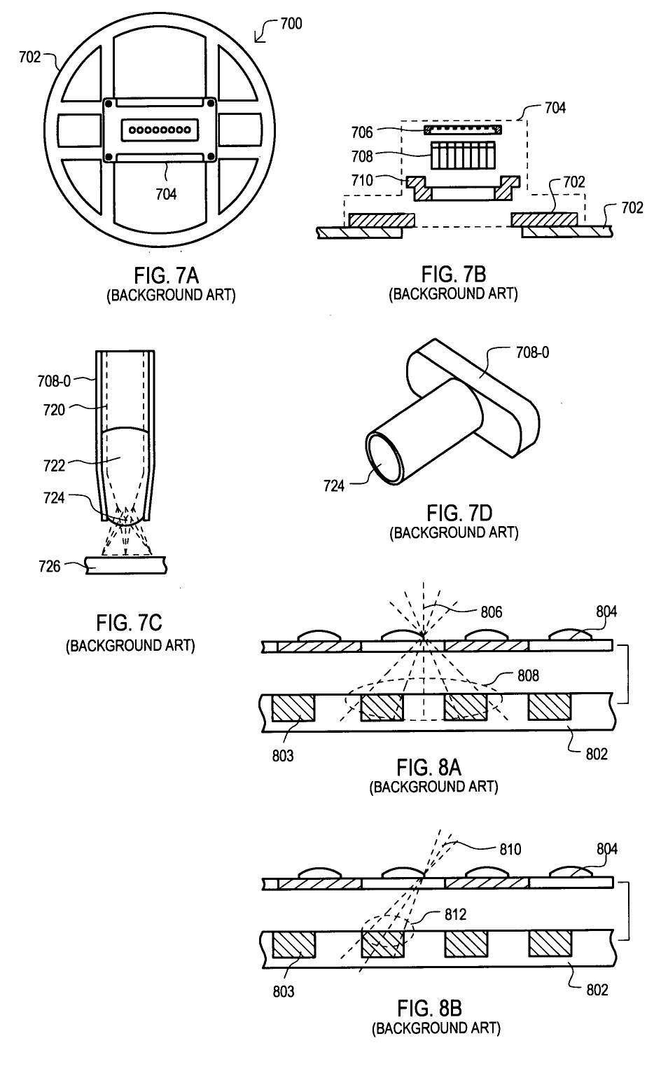

While embodiments of the present invention can test integrated circuits in wafer form, other embodiments can be used to test ICs in other forms. In particular, embodiments can test image sensor ICs in packaged form. One particular embodiment showing such an arrangement is shown in FIGS. 6A to 6D.

Referring now to FIG. 6A, a test device 600 can include a card portion 602 and a light providing assembly 604. A card portion 602 can include a top surface 606 having electrical connections (one shown as 612) to a DUT 614. Electrical connections 612 can be compatible with a packaged integrated circuit. In the example of FIG. 6A, a DUT 614 can have a “ball grid array” type interface, thus electrical connections 612 can be designed to compatible with such a pin arrangement. However, alternate embodiments can have electrical connections compatible with other package types, including but not limited to pin grid arrays, small outline (SOP) type packages, and inline pin type packages (e.g., DIP).

Referring still to FIG. 6A, a light providing assembly 604 can include an aperture 622 for directing light onto a DUT 614. An aperture 622 can be an essentially non-focusing aperture that does not include optics for focusing light onto a DUT 614. As in the embodiments above, preferably, an aperture 622 can provide light via “pin hole” optics. Light providing assembly 604 can include a horizontal portion 618-0 and, optionally, a vertical blocking portion 618-1. A light blocking portion 618-1 can extend from a horizontal portion 618-0 in a direction toward a DUT 614 and block light from being transmitted in a direction perpendicular to aperture 622.

In FIG. 6A, a DUT 614 can include a transparent cover 638, a die 640, and a package 642. A transparent cover 638 can allow light to be received by IC and converted into electrical data. Preferably, light providing assembly 614 can have dimensions “a” and “d” suitable to generate an image height “i” that covers a desired area of IC (e.g., an image sensor array). It is noted that a DUT 614 can be tested prior placement of transparent cover 638.

Referring now to FIG. 6B, a top plan view shows a testing arrangement that can correspond to the test system shown in FIG. 6A. FIG. 6B shows a tested DUT 614, which is in packaged form. FIG. 6B also show an image area 630 for DUT 614. Image area 630 can surround an image sensor array 632 of the DUT.

In this way, a test device can test ICs in packaged form, and not just wafer form.

Of course, other embodiments can test multiple packaged devices. One arrangement is shown in FIGS. 6C and 6D.

Referring now to FIG. 6C, a light providing assembly 654 is shown in a bottom plan view. Multiple apertures (622-0 to 222-3) can be surrounded by light blocking portion 618-1. Thus, light received from one aperture for one DUT can be prevented from interfering with an adjacent DUT.

FIG. 6D is a top plan view of a testing arrangement that can correspond to the test system shown in FIG. 6C. FIG. 6D shows a portion of a test device 650 that can hold four DUTs 614-0 to 614-3, arranged into a 2×2 array. A set of electrical connections (one shown as 612) can make contact with each DUT (614-0 to 614-3) to provide test signals to and from the devices. FIG. 6D shows image areas for each DUT, one of which is shown as 630, showing resulting area lit according to light passing through an aperture 612 of a light providing assembly 654.

In this way, multiple packaged image sensor devices can be tested with non-focusing light apertures.

While the above embodiments have been described with directions as “up” and “down”, such directions are not meant to limit the invention to any particular orientation in space. Test systems and/or corresponding DUTs can be oriented at different angles from, or inverted with respect to the various disclosed views.

Embodiments of the present invention are well suited to performing various other steps or variations of the steps recited herein, and in a sequence other than that depicted and/or described herein.

For purposes of clarity, many of the details of the various embodiments and the methods of designing and manufacturing the same that are widely known and are not relevant to the present invention have been omitted from the following description.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

It is also understood that the embodiments of the invention may be practiced in the absence of an element and/or step not specifically disclosed. That is, an inventive feature of the invention can be elimination of an element.

Accordingly, while the various aspects of the particular embodiments set forth herein have been described in detail, the present invention could be subject to various changes, substitutions, and alterations without departing from the spirit and scope of the invention.

What is claimed is:

1. An image sensing integrated circuit test device, comprising:
a plurality of conductive leads for making electrical contact with at least one integrated circuit device under test; and
a light directing structure for directing light onto the at least one integrated circuit device under test, the light directing structure comprising
a top member disposed in a lateral direction and having at least one aperture formed therein, and
for each aperture, a blocking member attached to the top member and disposed in a longitudinal direction around the aperture that prevents light arriving through the aperture from propagating in the lateral direction.

2. The test device of claim 1, wherein:
the test device comprises a wafer probe card for testing integrated devices formed in a wafer, the wafer probe card having a top surface, a bottom surface, and an opening therein; and
the directing structure is attached to the opening to provide a light transmission path through the wafer probe card.

3. The test device of claim 2, wherein:
the conductive leads are selected from the group consisting of:
probe needles that extend more in the lateral direction than in the longitudinal direction from the bottom surface of the wafer probe card, and
vertical probes that extend more in the longitudinal direction than in the lateral direction from the bottom surface of the wafer probe card.

4. The test device of claim 1, wherein:
the test device comprises a package tester for testing integrated devices in packaged form, the package tester including
a package receiving assembly for fixedly holding a packaged integrated circuit device, and
the conductive leads make electrical contact with terminals of the packaged integrated circuit.

5. The test device of claim 4, wherein:
the light directing structure is disposed over the package receiving assembly and the conductive leads.

6. The test device of claim 1, wherein:
the light directing structure is coupled to a position adjustor that allows the light directing structure to be variably positioned in a direction selected from the group consisting of: a first lateral direction, a second lateral direction perpendicular to the first lateral direction, and a longitudinal direction.

7. The test device of claim 1, wherein:
the at least one aperture is circular in cross section.

8. The test device of claim 1, wherein:
the at least one aperture is a pin hole opening void of any transparent material.

9. A method of testing an image sensing integrated circuit, comprising:
making an electrical connection to at least one integrated circuit via a plurality of conductive leads;
applying light to a surface of at least one integrated circuit via a corresponding non-focusing aperture; and
applying test signals to and receiving test signals from at the at least one integrated circuit.

10. The method of claim 9, wherein:
making an electrical connection to the at least one integrated circuit includes applying test probes to an integrated circuit formed in a wafer containing multiple integrated circuits.

11. The method of claim 10, wherein:
applying test probes includes applying probes selected from the group consisting of:
needle probes that extend longer in a direction parallel to a surface of the wafer than a direction perpendicular to the surface of the wafer, and
vertical probes that extend essentially only in a direction perpendicular to the surface of the wafer.

12. The test method of claim 10, wherein:
applying light to a surface of at least one integrated circuit includes applying light to a plurality of integrated circuits under test via a different non-focusing aperture corresponding to each integrated circuit under test; and
applying test signals to and receiving test signals from at the at least one integrated circuit includes applying test signals to and receiving test signals from the integrated circuits under test.

13. The test method of claim 12, wherein:
applying light to a surface of at least one integrated circuit includes preventing light from the non-focusing aperture of one of the integrated circuit under test from being transmitted to any other of the integrated circuits under test.

14. The test method of claim 12, wherein:
the multiple integrated circuits of the wafer are arranged into rows and columns perpendicular to such rows; and
the integrated circuits under test include integrated circuits of at least the same row.

15. The test method of claim 14, wherein:
the integrated circuits under test include integrated circuits of multiple rows.

16. The test method of claim 9, wherein:
making an electrical connection to the at least one integrated circuit includes applying test connections to at least one package containing the integrated circuit, the package having a light transmitting cover.

17. The test method of claim 9, wherein:
the at least one integrated circuit includes a substrate containing light detecting elements.

18. The test method of claim 17, wherein:
the at least one integrated circuit further includes any of the structures selected from the group consisting of: a plurality of microlenses formed over the substrate, and a plurality of color filters formed over the substrate.

19. A wafer test probe system, comprising:
a circuit board having an opening formed therein and a wafer facing side;
a light application element for placement into the opening having at least one pinhole opening for transmitting light through the circuit board to a DUT below without focusing such light; and
a plurality of conductive probes attached to the wafer facing side of the circuit board.

20. The wafer test system of claim 19, wherein:
the light application element comprises
a plurality of non-focusing pinhole openings, each for transmitting light to a corresponding integrated circuit of a wafer under test, and
a light blocking structure that prevents light originating from one pinhole from being transmitted to an integrated circuit other than the corresponding integrated circuit.
